(19) United States
(12) Patent Application Publication
(10) Pub. No.: US 2021/0193871 A1
(43) Pub. Date: Jun. 24, 2021

(54) REDUCTION IN LEAKAGE CURRENT AND INCREASE IN EFFICIENCY OF III-NITRIDE LEDS BY SIDEWALL PASSIVATION USING ATOMIC LAYER DEPOSITION

(71) Applicant: The Regents of the University of California, Oakland, CA (US)

(72) Inventors: Matthew S. Wong, Santa Barbara, CA (US); David Hwang, Windermere, FL (US); Abdullah Alhassan, Riyadh (SA); Steven P. DenBaars, Goleta, CA (US)

(73) Assignee: The Regents of the University of California, Oakland, CA (US)

(21) Appl. No.: 16/757,920

(22) PCT Filed: Oct. 31, 2018
(86) PCT No.: PCT/US18/58362

§ 371 Date: Apr. 21, 2020

Related U.S. Application Data
(60) Provisional application No. 62/580,287, filed on Nov. 1, 2017.

(51) Int. Cl. H01L 33/32; H01L 33/00; H01L 33/14; H01L 33/44

(52) U.S. Cl. CPC H01L 33/32; H01L 33/007; H01L 2933/0025; H01L 33/44; H01L 33/14

(57) ABSTRACT

A reduction in leakage current and an increase in efficiency of III-nitride LEDs is obtained by sidewall passivation using atomic layer deposition of a dielectric. Atomic layer deposition is a hydrogen-free deposition method, which avoids problems associated with the effects of hydrogen on passivation and transparency.

### CROSS REFERENCE TO RELATED APPLICATION

This application claims the benefit under 35 U.S.C. Section 119(e) of the following co-pending and commonly-assigned application:

U.S. Provisional Patent Application No. 62/580,287, filed on Nov. 1, 2017, by Matthew S. Wong, David Hwang, Abdullah Alhassan, and Steven P. DenBaars, entitled “REDUCTION IN LEAKAGE CURRENT AND INCREASE IN EFFICIENCY OF III-NITRIDE LEDS BY SIDEWALL PASSIVATION USING ATOMIC LAYER DEPOSITION,” attorney's docket number 30794.0667USP1 (UC 2018-256-1);

which application is incorporated by reference herein.

### BACKGROUND OF THE INVENTION

### 1. Field of the Invention

This invention relates to a reduction in leakage current and an increase in efficiency of III-nitride light-emitting diodes by sidewall passivation using atomic layer deposition.

### 2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

III-nitride light-emitting diodes (LEDs) have been well developed for solid-state lighting applications, where the term “III-nitride” refers to any alloy composition of the (Ga, Al, In, B)N semiconductors having the chemical formula of Ga_{w}AlₓIn_{y}B_{z}N where 0≤w≤1, 0≤x≤1, 0≤y≤1, 0≤z≤1 and w+x+y+z=1.

Recently, there has been increasing research attention on III-nitride micron-sized LEDs, which are commonly referred to as μLEDs, where the μLEDs are sized less than 100 μm². μLEDs can be used for various display applications, such as near-eye displays and displays for mobile devices, due to the chemical robustness, the long operating lifetime, high efficiency, and high contrast ratio of III-nitride LEDs.

Because of the chemical inertness of III-nitrides, plasma-based dry etching is commonly employed in the fabrication of III-nitride devices, such as μLEDs. As a result, defects and surface states will be introduced on the sidewall of the devices due to the barbaric characteristic of dry etching. Moreover, defects and surface states serve as charge carrier traps, and increase leakage current and the probability of non-radiative recombination, which lead to reductions in the probability of radiative recombination and the efficiency of III-nitride LEDs. [1]

To reduce the negative effects of dry etching, one method is to deposit dielectric materials, such as SiO₂, SiNₓ, Al₂O₃, or other insulating materials, to passivate the sidewall and to bury the defects and surface states. Plasma-enhanced chemical vapor deposition (PECVD) is the conventional deposition method for dielectrics, because it provides a rapid deposition rate.

However, PECVD typically uses hydrogen-containing precursors, such as silane, which can be problematic for III-nitride LEDs. First, Mg-doped III-nitride, which is the most common way to obtain p-type III-nitride, is sensitive to hydrogen and can form complexes with hydrogen and lead to increase in resistivity of the p-doped layer. Additionally, as the size of III-nitride LEDs is reduced, hydrogen is easier to diffuse into the LEDs and lowers the efficiency of the LEDs.

Besides, to compensate the low-conductivity of the p-doped layer of III-nitrides, a conductive spreading layer is used as a current spreading layer to spread the current in the p-doped layer. Indium-tin oxide (ITO) is a typical candidate for the conductive spreading layer, because it has been well studied and demonstrated in many LED designs, and yields a property of high transparency. However, hydrogen radicals generated from the PECVD process can react with the ITO interface to create metallic indium and tin (IV) oxide, which decreases the transparency of the ITO and results in less light being extracted from the LEDs.

Thus, there is a need for improved methods of passivating sidewalls of III-nitride LEDs. The present invention satisfies that need.

### SUMMARY OF THE INVENTION

The present invention discloses a reduction in leakage current and an increase in efficiency of III-nitride LEDs obtained by sidewall passivation using atomic layer deposition (ALD) of dielectrics. ALD is a hydrogen-free deposition method, which avoids the problems associated with the effects of hydrogen on passivation and transparency.

### BRIEF DESCRIPTION OF THE DRAWINGS

Referring now to the drawings in which like reference numbers represent corresponding parts throughout:

FIG. 1 is a schematic of an opto-electronic device comprised of a plurality of III-nitride layers, according to one embodiment.

FIG. 2 illustrates the process for fabricating the opto-electronic device, according to one embodiment, according to one embodiment.

FIG. 3 is a graph of leakage current (mA) vs. voltage (V) in LEDs with different passivation techniques.

FIG. 4 are electroluminescence images of LEDs with different passivation techniques.

FIG. 5(a) is a graph of external quantum efficiency (EQE) (%) vs. current density (A/cm²) for large LEDs, and FIG. 5(b) is a graph of external quantum efficiency (EQE) (%) vs. current density (A/cm²) for small LEDs, with different passivation techniques.

FIG. 6 is a graph of leakage current density (A/cm²) vs. μLED dimensions (μm²) with different passivation techniques.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

This invention describes sidewall passivation for III-nitride LEDs using dielectrics, such as SiO₂, SiNₓ, Al₂O₃, deposited by ALD. The result is a reduction in leakage current and increase in efficiency for the III-nitride LEDs.

As noted above, due to the chemical inertness of III-nitrides semiconductor materials, plasma-based dry etching is widely employed to define the mesa structure of III-nitride LEDs. [1] As a consequence of the barbaric-etch nature of plasma, the sidewalls of the LEDs have defects and surface states caused by the etch, which results in leakage current and reduction of internal quantum efficiency, due to non-radiative recombination of the surface states. [1,2]

Sidewall passivation using dielectrics has been demonstrated and used to decrease the leakage current of the III-nitride LEDs. [3] Moreover, PECVD is a common technique for the deposition of dielectrics to passivate the sidewalls of III-nitride LEDs. [4,5] However, as the size of the LEDs is reduced, the adverse influence of PECVD becomes more pronounced on the performance of the LEDs.

One of main drawbacks of using PECVD is the reduction of light extraction. In a typical, commercially available, III-nitride LED, a current spreading layer is usually deposited between the p-doped layer and the metal contacts due to the highly resistive nature of the p-doped layer. Furthermore, transparent conductive oxides (TCOs), such as indium-tin oxide (ITO), are commonly employed as the current spreading layer because of their high transparency and conductivity. From the literature, the effects of PECVD on ITO have been studied, where the transparency of ITO is decreased, because the ITO is reduced by the hydrogen generated from the PECVD process. [6]

Additionally, since a large amount of hydrogen is formed from the hydrogen-containing precursors during the PECVD process, hydrogen can passivate the p-doped layer by diffusion. The result of hydrogen passivation in the p-doped layer should increase its resistivity.

On the other hand, ALD has atomic-scale control on the deposition rate of dielectric thin films, and the dielectric thin films are sufficient to passivate the sidewall of the LEDs and to reduce leakage current for the LEDs. More importantly, ALD is a hydrogen-free deposition method, which should be able to avoid the problem of hydrogen passivation.

The influences of PECVD on large LEDs may not be significant because of the large light-emitting area. However, for μLEDs, the light emitting from the device is remarkably less, and therefore small differences in transparency can have dramatic effects on the efficiency of LEDs. Moreover, the impact of hydrogen passivation can be notable due to the small emitting area for μLEDs.

Device Structure and Fabrication Process

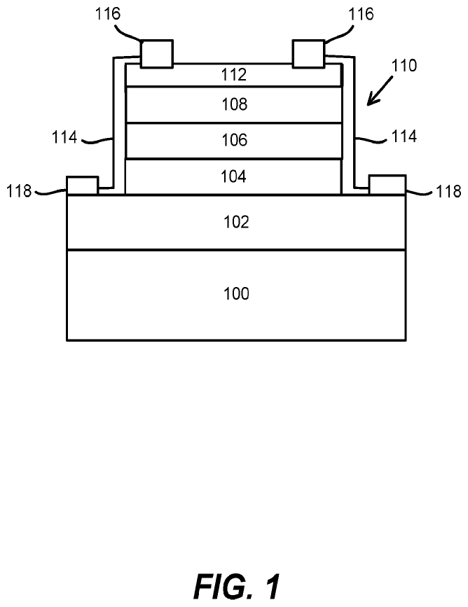

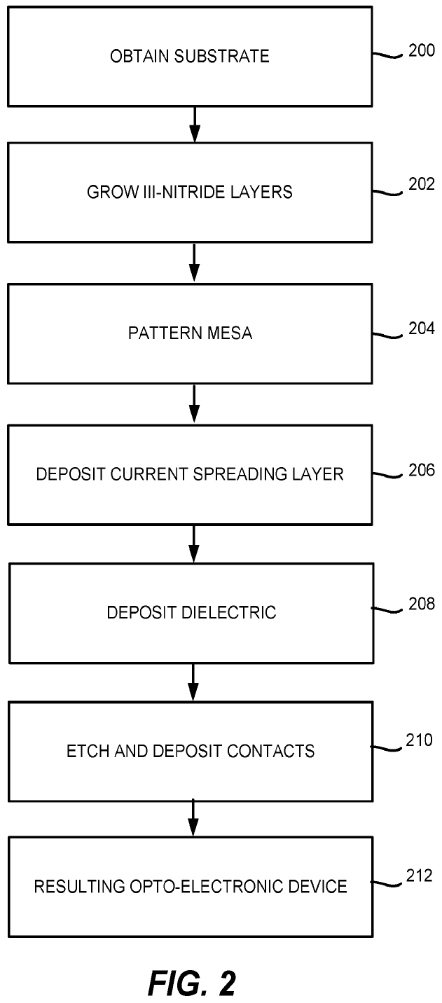

FIG. 1 is a schematic of an exemplary opto-electronic device comprised of a plurality of III-nitride layers, wherein reference numbers in the 100's refer to device structures, and FIG. 2 illustrates the process for fabricating the opto-electronic device, wherein reference numbers in the 200's refer to process steps, according to one embodiment. The device may comprise a light-emitting diode (LED), a laser diode (LD), a solar cell, a photo-detector, or other opto-electronic device.

A GaN substrate 100 is obtained (step 200), and III-nitride layers are grown upon the substrate 100 (step 202). The III-nitride layers include, but are not limited to, one or more n-type GaN layers 102 and 104, an active region 106 comprised of, for example, InGaN/GaN multiple quantum wells (MQW), and a p-type GaN layer 108. The device structure may be grown by metalorganic chemical vapor deposition (MOCVD) or molecular beam epitaxy (MBE), for example.

The device structure is further processed to form a mesa 110 by patterning using a dry etch to define the device area (step 204). Then, a current spreading layer 112, such as ITO, is deposited on the p-type layer 108 (step 206).

Thereafter, at least one sidewall of the mesa 110 is passivated by depositing a dielectric thin film 114 using a hydrogen-free deposition, such as by ALD (step 208). The dielectric may comprise SiO₂, SiNₓ, Al₂O₃, or another insulating oxide or nitride.

The hydrogen-free deposition of the dielectric 114 by ALD reduces leakage current from the device, as compared to deposition of a dielectric by a hydrogen-based deposition, such as by PECVD. In addition, the hydrogen-free deposition of the dielectric 114 by ALD increases the efficiency of the device, as compared to deposition of a dielectric by a hydrogen-based deposition, such as by PECVD. The hydrogen-free deposition of the dielectric 114 by ALD also has less impact on the transparency of the current spreading layer 112, as compared to a hydrogen-based deposition of a dielectric, such as by PECVD.

A hydrofluoric (HF) etch is used to open windows in the dielectric 114 for the deposition of metallic pads and contacts, namely, deposition of p-contacts 116 onto the current spreading layer 112 and deposition of n-contacts 118 onto the n-type layer 102 (step 210).

Finally, the end result (step 212) of the process comprises the opto-electronic device of FIG. 1 fabricated according to the method of FIG. 2.

Experimental Results

As a demonstration, III-nitride LED samples were fabricated, and a dielectric thin film comprised of SiO₂ with a thickness of about 50 nm was deposited on the sidewalls of the III-nitride LED samples using both ALD and PECVD, followed by an HF etch to open windows for metal pads and contacts. The ALD was performed at a temperature greater than about 25° C. In addition, III-nitride LED samples with no passivation were fabricated as a reference. Thereafter, the devices were characterized.

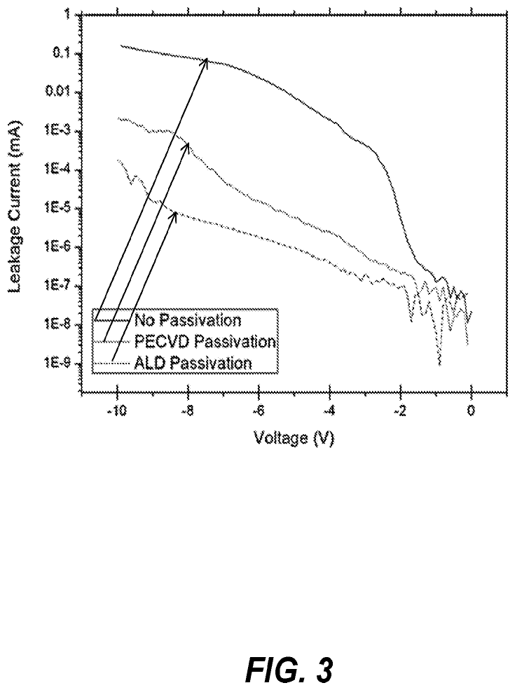

FIG. 3 is a graph of leakage current (mA) vs. voltage (V) for III-nitride LED samples with no sidewall passivation, with sidewall passivation by PECVD, and with sidewall passivation by ALD. The plots for each sample show that the III-nitride LED samples with sidewall passivation by ALD or PECVD can reduce the leakage current, as compared to the III-nitride LED samples with no sidewall passivation.

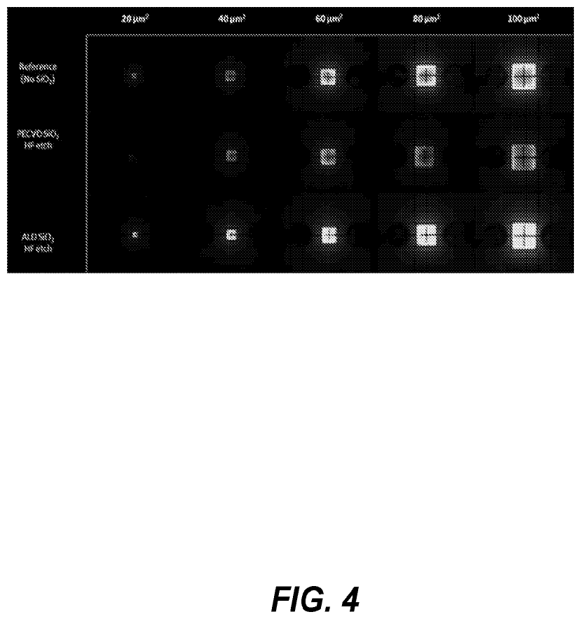

FIG. 4 are electroluminescence images of III-nitride LED samples of different sizes (indicated by the columns labeled 20 μm², 40 μm², 60 μm², 80 μm², 100 μm²) treated with different passivation techniques or no passivation, and operated at a current density of 1 A/cm². No passivation and the different passivation techniques are indicated by the rows labeled as Reference (No SiO₂), PECVD SiO₂/HF etch, and ALD SiO₂/HF etch.

The differences between the III-nitride LEDs with no passivation, namely Reference (No SiO₂), as well as the different passivation techniques, namely PECVD SiO₂/HF etch and ALD SiO₂/HF etch, are significant. The III-nitride LED samples passivated via PECVD appear to be dimmer than the III-nitride LED samples passivated via ALD and the III-nitride LED samples with no passivation. This is because the ITO layer is damaged by the hydrogen from the PECVD process, whereas the ITO layer is undamaged for the III-nitride LED samples passivated via ALD and with no passivation.

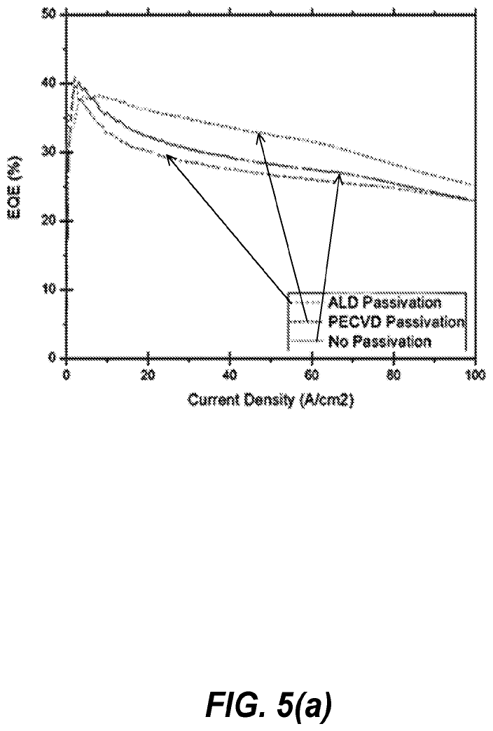

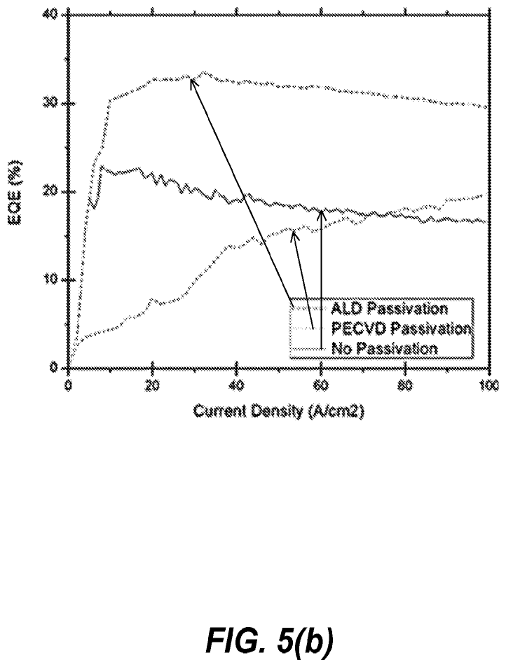

Furthermore, to determine the efficiency of the III-nitride LEDs, the EQE (%) vs. current density (A/cm²) of two different sizes of the III-nitride LED were measured, as shown in FIGS. 5(a) and 5(b). The two different LED sizes are 100 μm² in FIG. 5(a) and 20 μm² in FIG. 5(b).

In FIG. 5(a), the peak EQE is identical for the large LED samples with no passivation, as well as the LED samples passivated on the sidewall via ALD or PECVD, because the perimeter/area ratio is small in large LEDs and the effect of sidewall damage is insignificant in large LEDs.

In FIG. 5(b), however, the peak EQE is very different for the small LED samples. The LED sample passivated via ALD results in the highest EQE and the LED sample passivated via PECVD yields the worst performance, in the low current density regime. The phenomenon can be explained by the difference in the ratio of sidewall perimeter/mesa area. [7]

In the large 100 μm² LED samples, the mesa area is remarkably greater than the sidewall perimeter, the ratio of sidewall perimeter/mesa area is insignificant, the area that is affected by the plasma damage from dry etching is trivial, and light is emitted from an undamaged active region.

In the small 20 μm² LED samples, the ratio of sidewall perimeter/mesa area is significant, and the active region can be affected by plasma damage, which decreases the probability of radiative recombination. Moreover, although the light emitted from the LED samples passivated via PECVD is less than from the LED samples passivated via ALD, due to the less transparent ITO layer at 1 A/cm², the ITO barrier can be overcome at higher current density for large devices, but not for small devices, because large devices have greater area to generate more light intensity and small devices have less area to emit light. As a result, the EQE of the LED passivated via PECVD is the worst at low current density, because light is obstructed by the ITO layer.

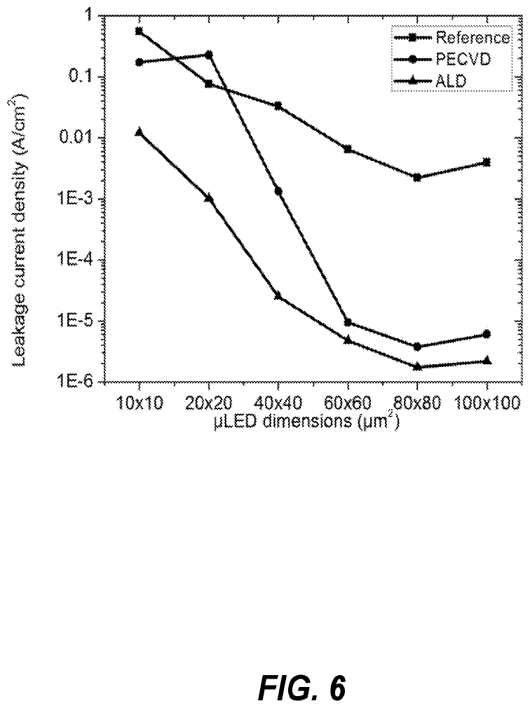

To compare the effectiveness of different sidewall passivation methods, the leakage current at −4 V is measured and shown in FIG. 6, as well as the following table:

Leakage Current Density at −4V

| Size | Reference | PECVD | ALD |
|---|---|---|---|
| 10×10 | 0.54771 | 0.17147 | 0.0121 |
| 20×20 | 0.07576 | 0.22727 | 0.00101 |
| 40×40 | 0.03279 | 0.00132 | 2.52E−05 |
| 60×60 | 0.00644 | 9.53E−06 | 4.76E−06 |
| 80×80 | 0.00221 | 3.78E−06 | 1.73E−06 |
| 100×100 | 0.00393 | 6.05E−06 | 2.22E−06 |

ALD passivation has the least amount of leakage current among all sizes. PECVD passivation shows a rapid increase in leakage current to the same order of magnitude as the devices without sidewall passivation when decreasing the dimensions from 60×60 μm² to 20×20 μm². This reveals that PECVD is insufficient to passivate the sidewall and reduce leakage in small dimensions of LEDs. Moreover, the difference in leakage current between ALD and PECVD is more than 10 orders of magnitude in the devices of 10×10 μm² and 20×20 μm², which indicates ALD is a better passivation method to employ for LEDs with small sizes.

Benefits and Advantages

In order to obtain μLEDs with high energy efficiency, leakage current should be reduced below 1E-6A. As described herein, sidewall passivation of μLEDs using ALD should be sufficient to reduce leakage current.

Alternatives and Modifications

The scope of this invention covers III-nitride laser diodes (LDs), solar cells and photo-detectors, as well as III-nitride LEDs.

### REFERENCES

The following references are incorporated by reference herein:
1. Lee, J.-M., Huh, C., Kim, D.-J. & Park, S.-J. Dry-etch damage and its recovery in InGaN/GaN multi-quantum-well light-emitting diodes. Semicond. Sci. Technol. 18, 530-534 (2003).
2. Lee, J. M. et al. Dry etch damage in n-type GaN and its recovery by treatment with an N₂ plasma. J. Appl. Phys. 87, 7667-7670 (2000).
3. Chen, W. et al. High-performance, single-pyramid micro light-emitting diode with leakage current confinement layer. Appl. Phys. Express 8, (2015).
4. Liu, H. et al. Al₂O₃Passivation Layer for InGaN/GaN LED Deposited by Ultrasonic Spray Pyrolysis. IEEE Photonics Technol. Lett. 26, 1243-1246 (2014).
5. Choi, W. H. et al. Sidewall passivation for InGaN/GaN nanopillar light emitting diodes. J. Appl. Phys. 116, (2014).
6. Son, K. S., Choi, D. L., Lee, H. N. & Lee, W. G. The interfacial reaction between ITO and silicon nitride deposited by PECVD in fringe field switching device. Current Applied Physics, vol. 2, issue 3, pp. 229-232 (2002).
7. Hwang, D., Mughal, A., Pynn, C. D., Nakamura, S. & DenBaars, S. P. Sustained high external quantum efficiency in ultrasmall blue II-nitride micro-LEDs. Appl. Phys. Express 10, 32101 (2017).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
fabricating an opto-electronic device comprised of a plurality of II-nitride layers; and
passivating at least one sidewall of the device using a hydrogen-free deposition of a dielectric.

2. The method of claim 1, wherein the hydrogen-free deposition of the dielectric comprises an atomic layer deposition (ALD) of the dielectric.

3. The method of claim 2, wherein the atomic layer deposition of the dielectric is performed at a temperature greater than about 25° C.

4. The method of claim 1, wherein the hydrogen-free deposition of the dielectric reduces leakage current from the device, as compared to a hydrogen-based deposition of a dielectric.

5. The method of claim 1, wherein the hydrogen-free deposition of the dielectric increases the device's efficiency, as compared to a hydrogen-based deposition of a dielectric.

6. The method of claim 1, wherein the device includes a transparent conductive oxide (TCO) as a current spreading layer, and the hydrogen-free deposition of the dielectric has less impact on transparency of the current spreading layer, as compared to a hydrogen-based deposition of a dielectric.

7. The method of claim 1, wherein the dielectric is SiO₂, SiNₓ, Al₂O₃, or another insulating oxide or nitride.

8. The method of claim 1, wherein the device is a light-emitting diode (LED).

9. The method of claim 1, wherein the device is a laser diode (LD).

10. The method of claim 1, wherein the device is a solar cell.

11. The method of claim 1, wherein the device is a photo-detector.

12. A device fabricated according to the method of claim 1.
